(19) United States
(12) Patent Application Publication
(10) Pub. No.: US 2025/0277835 A1
(43) Pub. Date: Sep. 4, 2025

(54) LOAD RESISTANCE VALUE DETERMINATION METHOD, APPARATUS, ELECTRONIC DEVICE AND STORAGE MEDIUM

(71) Applicant: CHENGDU CONVENIENTPOWER SEMICONDUCTOR CO. LTD., Chengdu (CN)

(72) Inventors: Yihong DAI, Chengdu (CN); Zufeng GUO, Chengdu (CN); Fangming AN, Chengdu (CN)

(73) Assignee: CHENGDU CONVENIENTPOWER SEMICONDUCTOR CO. LTD., Sichuan (CN)

(21) Appl. No.: 18/846,268

(22) PCT Filed: Dec. 30, 2022
(86) PCT No.: PCT/CN2022/144034

§ 371 Date: Sep. 12, 2024

(30) Foreign Application Priority Data
Nov. 24, 2022 (CN) 202211478681.3

(51) Int. Cl. G01R 27/08

(52) U.S. Cl. CPC G01R 27/08

(57) ABSTRACT

A load resistance value determination method, an apparatus, an electronic device and a storage medium are provided The load resistance value determination method is applied to a controller of a signal transmitting circuit. The signal transmitting circuit further includes a bridge circuit, a load network and a current detection module. The bridge circuit is connected with the load network, the current detection module and the controller, respectively. Firstly, a drive signal is sent to the bridge circuit so as to drive one loop of the signal transmitting circuit to conduct, then average current collected by the current detection module is acquired, and a resistance value of a load resistor of the signal transmitting circuit is determined according to a voltage of the power input end, a duty cycle and the average current.

### CROSS-REFERENCE TO RELATED APPLICATION

The present disclosure claims the priority to the Chinese patent application with the filing No. 202211478681.3 filed on Nov. 24, 2022 with the China National Intellectual Property Administration and entitled “LOAD RESISTANCE VALUE DETERMINATION METHOD, APPARATUS, ELECTRONIC DEVICE AND STORAGE MEDIUM”, the contents of which are incorporated by reference herein in entirety.

### TECHNICAL FIELD

The present disclosure relates to the field of resistance value determination technologies, and specifically to a load resistance value determination method, an apparatus, an electronic device and a storage medium.

### BACKGROUND ART

In signal transmitting circuits, some important parameters need to be acquired, such as duty cycle of a control signal controlling conduction of a bridge circuit, and the duty cycle may be determined by a resistance value of a load resistor of the whole circuit. However, the resistance value of the load resistor in the prior art generally is a preset fixed value, and thus the duty cycle of the control signal is also a fixed value, which is not flexible for controlling the bridge circuit.

In conclusion, there exists a problem in the prior art that it is not flexible to control the bridge circuit.

### SUMMARY

The present disclosure aims at providing a load resistance value determination method, an apparatus, an electronic device and a storage medium, so as to solve the problem in the prior art that it is not flexible to control the bridge circuit.

In order to achieve the above objective, technical solutions adopted in the present disclosure are as follows.

In the first aspect, embodiments of the present disclosure provide a load resistance value determination method, applied to a controller of a signal transmitting circuit. The signal transmitting circuit further includes a bridge circuit, a load network and a current detection module. The bridge circuit is connected with the load network, the current detection module and the controller, respectively. The current detection module is further connected with the controller and a power input end, respectively. The method includes steps of:
sending a drive signal to the bridge circuit so as to drive one loop of the signal transmitting circuit to conduct;
acquiring average current collected by the current detection module; and
determining a resistance value of a load resistor of the signal transmitting circuit according to a voltage of the power input end, a duty cycle of the drive signal and the average current.

Optionally, the resistance value of the load resistor of the signal transmitting circuit is proportional to the voltage of the power input end, proportional to square of the duty cycle of the drive signal, and inversely proportional to the average current.

Optionally, the step of sending a drive signal to the bridge circuit includes:
sending the drive signal with a duty cycle greater than 0 and less than 10% to the bridge circuit.

Optionally, the bridge circuit includes a first switch, a second switch, a third switch and a fourth switch. Control terminals of the first switch, the second switch, the third switch and the fourth switch are all connected with the controller. A first terminal of the first switch and a first terminal of the fourth switch are connected with the current detection module. A second terminal of the first switch is connected with the load network and a first terminal of the second switch respectively. A second terminal of the fourth switch is connected with the load network and a first terminal of the third switch, respectively. A second terminal of the second switch and a second terminal of the third switch are grounded.

The step of sending a drive signal to the bridge circuit so as to drive one loop of the signal transmitting circuit to conduct includes:
sending a first drive signal to the bridge circuit, so as to drive a loop where the first switch and the third switch are located to conduct according to a preset duty cycle, and the second switch and the fourth switch are turned off; or
sending a second drive signal to the bridge circuit, so as to drive a loop where the second switch and the fourth switch are located to conduct according to a preset duty cycle, and the first switch and the third switch are turned off.

In the second aspect, embodiments of the present disclosure further provide a load resistance value determination apparatus, applied to a controller of a signal transmitting circuit. The signal transmitting circuit further includes a bridge circuit, a load network and a current detection module. The bridge circuit is connected with the load network, the current detection module and the controller, respectively. The current detection module is further connected with the controller and a power input end, respectively. The apparatus includes:
a sending unit, configured to send a drive signal to the bridge circuit, so as to drive one loop of the signal transmitting circuit to conduct;
an acquiring unit, configured to acquire average current collected by the current detection module; and
a processing unit, configured to determine a resistance value of a load resistor of the signal transmitting circuit according to a voltage of the power input end, a duty cycle of the drive signal and the average current.

Optionally, the resistance value of the load resistor of the signal transmitting circuit is proportional to the voltage of the power input end, proportional to square of the duty cycle of the drive signal, and inversely proportional to the average current.

Optionally, the sending unit is configured to send the drive signal with a duty cycle greater than 0 and less than 10% to the bridge circuit.

Optionally, the bridge circuit includes a first switch, a second switch, a third switch and a fourth switch. Control terminals of the first switch, the second switch, the third switch and the fourth switch are all connected with the controller. A first terminal of the first switch and a first terminal of the fourth switch are connected with the current detection module. A second terminal of the first switch is connected with the load network and a first terminal of the second switch, respectively. A second terminal of the fourth switch is connected with the load network and a first terminal of the third switch, respectively. A second terminal of the second switch and a second terminal of the third switch are grounded.

The sending unit is configured to send a first drive signal to the bridge circuit, so as to drive a loop where the first switch and the third switch are located to conduct according to a preset duty cycle, and the second switch and the fourth switch are turned off; or
send a second drive signal to the bridge circuit, so as to drive a loop where the second switch and the fourth switch are located to conduct according to a preset duty cycle, and the first switch and the third switch are turned off.

In the third aspect, embodiments of the present disclosure further provide an electronic device, including:
a memory, configured to store one or more programs; and
a processor, wherein
the one or more programs, when executed by the processor, implements the above method.

In the fourth aspect, embodiments of the present disclosure further provide a computer readable storage medium, storing a computer program thereon, wherein the computer program, when executed by a processor, implements the above method.

Compared with the prior art, embodiments of the present disclosure provide a load resistance value determination method, an apparatus, an electronic device and a storage medium. The load resistance value determination method is applied to a controller of a signal transmitting circuit. The signal transmitting circuit further includes a bridge circuit, a load network and a current detection module. The bridge circuit is connected with the load network, the current detection module and the controller, respectively. The current detection module is further connected with the controller and a power input end, respectively. Firstly, a drive signal is sent to the bridge circuit so as to drive one loop of the signal transmitting circuit to conduct, then average current collected by the current detection module is acquired, and a resistance value of a load resistor of the signal transmitting circuit is determined according to a voltage of the power input end, a duty cycle and the average current. Since the present disclosure can determine the resistance value of the load resistor according to the voltage of the power input end, the duty cycle and the average current, the effect of flexibly determining the resistance value of the load resistor is realized, so that it is more flexible to control the bridge circuit.

### BRIEF DESCRIPTION OF DRAWINGS

In order to more clearly illustrate technical solutions of embodiments of the present disclosure, drawings which need to be used in the embodiments will be briefly introduced below. It should be understood that the drawings below merely show some embodiments of the present disclosure, and thus should not be considered as limitation to the scope. Those ordinarily skilled in the art still could obtain other relevant drawings according to these drawings, without using any inventive efforts.

FIG. 1 is a circuit schematic diagram of a signal transmitting circuit in the prior art.

FIG. 2 is another circuit schematic diagram of a signal transmitting circuit in the prior art.

FIG. 3 is a circuit schematic diagram of a signal transmitting circuit provided in embodiments of the present disclosure.

FIG. 4 is a modular schematic diagram of an electronic device provided in embodiments of the present disclosure.

FIG. 5 is an exemplary flow chart of a load resistance value determination method provided in embodiments of the present disclosure.

FIG. 6 is a waveform diagram of various signals provided in embodiments of the present disclosure.

FIG. 7 is a modular schematic diagram of a load resistance value determination apparatus provided in embodiments of the present disclosure.

In the drawings: 100—electronic device; 101—processor; 102—memory; 103—communication interface; 200—load resistance value determination apparatus; 210—sending unit; 220—acquiring unit; 30—processing unit.

### DETAILED DESCRIPTION OF EMBODIMENTS

In order to make the objectives, technical solutions and advantages of the embodiments of the present application clearer, the technical solutions in the embodiments of the present disclosure will be described clearly and completely below in combination with the drawings of the embodiments of the present disclosure. Apparently, the embodiments described are some but not all embodiments of the present disclosure. Generally, components in the embodiments of the present disclosure described and shown in the drawings herein may be arranged and designed in various different configurations.

Therefore, the following detailed description of the embodiments of the present disclosure provided in the drawings is not intended to limit the claimed scope of the present disclosure, but merely represents selected embodiments of the present disclosure. Based on the embodiments in the present disclosure, all of other embodiments obtained by those ordinarily skilled in the art without using any inventive efforts shall fall within the scope of protection of the present disclosure.

It should be noted that like reference signs and letters represent like items in the following drawings, and thus, once a certain item is defined in one drawing, it is not needed to be further defined or explained in subsequent drawings. Meanwhile, in the description of the present disclosure, terms such as “first” and “second” are merely used to distinguish the description, but should not be construed as indicating or implying importance in the relativity.

It should be indicated that herein, relational terms such as first and second are merely used to distinguish one entity or operation from another entity or operation, while it is not necessarily required or implied that these entities or operations have any such practical relation or order. Moreover, terms such as “comprise”, “contain” or any other variants thereof are intended to encompass non-exclusive inclusion, so that a process, a method, an article or an apparatus including a series of elements not only includes those elements, but also includes other elements that are not explicitly listed, or further includes elements inherent in such process, method, article or apparatus. Without more limitations, an element defined by the phrase “including a . . . ” does not exclude inclusion of other same elements in the process, method, article or apparatus including the element.

In the description of the present disclosure, it should be indicated that orientation or positional relationships indicated by the terms such as “upper”, “lower”, “inner”, and “outer” are based on orientation or positional relationships as shown in the drawings, or orientation or positional relationships of a product of the present disclosure when being conventionally placed in use, merely for facilitating describing the present disclosure and simplifying the description, rather than indicating or implying that related apparatus or element has to be in the specific orientation or configured and operated in a specific orientation, and thus they should not be construed as limitation to the present disclosure.

In the description of the present disclosure, it should also be indicated that, unless clearly defined and limited otherwise, the terms “provide” and “connect” should be understood in a broad sense, for example, it may be a fixed connection, a detachable connection, or an integral connection; it may be a mechanical connection or an electrical connection; it may be direct connection, indirect connection through an intermediary, or internal communication between two components. The specific meanings of the above terms in the present disclosure could be understood by those skilled in the art according to specific situations.

Some embodiments of the present disclosure are described in detail below in combination with the drawings. The following embodiments and the features in the embodiments may be combined with each other without conflict.

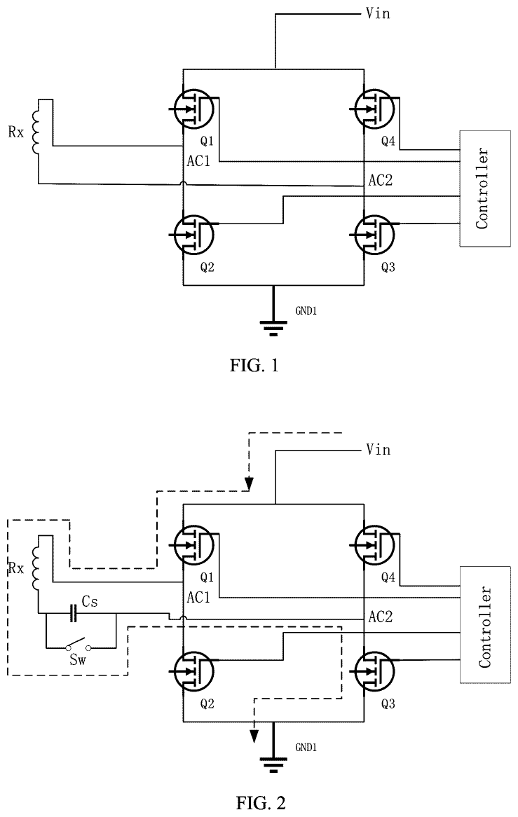

As shown in FIG. 1, it is a schematic diagram of a signal transmitting circuit in the prior art. A full-bridge circuit is used to form a loop with a load network. The load network includes an inductor Rx. When a controller outputs a control signal, to control Q1 and Q3 to conduct and control Q2 and Q4 to be turned off, current flows from AC1 to AC2; and when the controller outputs a control signal, to control Q2 and Q4 to conduct, and control Q1 and Q3 to be turned off, current flows from AC2 to AC1.

In another implementation mode of the prior art, referring to FIG. 2, the load network further may include a capacitor Cs and a switch Sw, wherein the capacitor Cs and the switch Sw are configured to control operation modes of a signal transmitting circuit. The operation modes of the signal transmitting circuit include a wireless charging mode and a signal transmission mode. That is, in the signal transmitting circuit shown in FIG. 2, switching between the wireless charging mode and the signal transmission mode can be realized through the switch Sw.

Specifically, when the switch Sw is closed, it is equivalent to the capacitor Cs being short-circuited. In this case, the inductor Rx is directly connected to midpoint points AC1 and AC2 of bridge arms of the full-bridge circuit, and in this case, the signal transmitting circuit is in a signal transmission mode, and the signal transmitting circuit is configured to realize signal transmission. When the switch Sw is opened, the capacitor Cs is added between the inductor Rx and the midpoint AC2 of the bridge arm, the signal transmitting circuit is in the wireless charging mode, and the signal transmitting circuit is configured to realize energy transmission.

It should be indicated that, the full-bridge circuit is adopted in both examples in FIG. 1 and FIG. 2, but in actual application, a half-bridge circuit also may be adopted, which is not limited herein.

It should be further indicated that, the signal transmitting circuits hereinafter all operate in the signal transmission mode, that is, the switch Sw is always closed.

On this basis, as shown by dotted lines in FIG. 2, in this case, Q1 and Q3 in the signal transmitting circuit are conducting, Q2 and Q4 are turned off, and current flows along a loop marked by the dotted lines, thereby realizing a function of measuring a resistance value of a load resistor.

A resistance value of a load resistor in a signal transmitting circuit may be used to determine a duty cycle of a control signal. However, the resistance value of the load resistor in the signal transmitting circuit currently is generally a fixed value, and thus the duty cycle of the control signal is fixed, which is not flexible for controlling the bridge circuit.

In view of this, the present disclosure provides a load resistance value determination method, wherein by acquiring a voltage of a power input end, a duty cycle of a drive signal and average current, a resistance value of a load resistor in a whole signal transmitting circuit is determined, so as to realize flexible control.

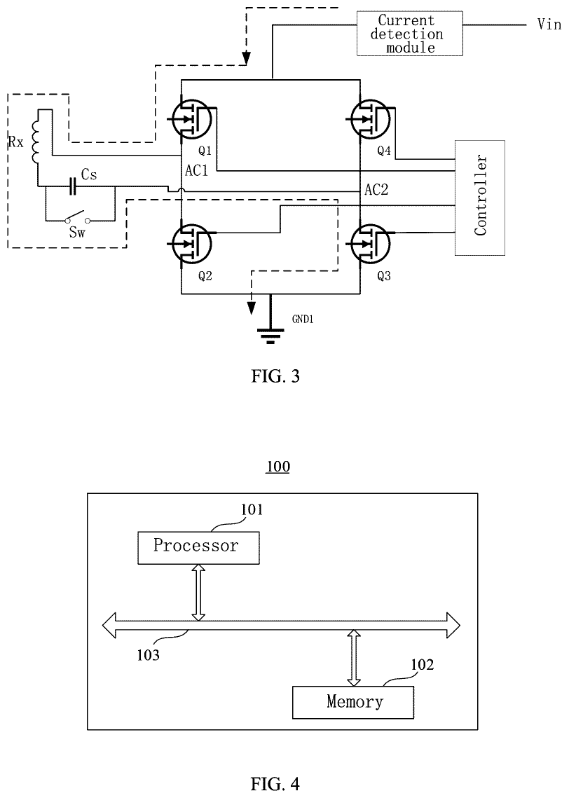

It should be indicated that the load resistance value determination method provided in the present disclosure may be applied to an electronic device 100, for example, to a controller of a signal transmitting circuit. Referring to FIG. 3, the signal transmitting circuit further includes a bridge circuit, a load network and a current detection module. The bridge circuit is connected with the load network, the current detection module and the controller, respectively. The current detection module is further connected with the controller and a power input end Vin, respectively.

As an implementation mode, FIG. 4 shows a schematic structural block diagram of an electronic device provided in the present disclosure. The electronic device includes a memory 102, a processor 101 and a communication interface 103, wherein the memory 102, the processor 101 and the communication interface 103 are electrically connected directly or indirectly with each other, so as to realize transmission or interaction of data. For example, these elements may be electrically connected with each other via one or more communication buses or signal lines.

The memory 102 may be configured to store software programs and modules, such as program instructions or modules corresponding to the load resistance value determination apparatus provided in the embodiments of the present disclosure, and the processor 101 executes various functional applications and data processing by executing the software programs and modules stored in the memory 102, so as to execute the steps of the load resistance value determination method provided in the embodiments of the present disclosure. The communication interface 103 may be configured to perform communication of signaling or data with other node devices.

In the above, the memory 102 may be, but not limited to, random access memory (RAM), read only memory (ROM), programmable read-only memory (PROM), erasable programmable read-only memory (EPROM), electric erasable programmable read-only memory (EEPROM) and so on.

The processor 101 may be an integrated circuit chip, with a signal processing function. The processor 101 may be a general-purpose processor, including a central processing unit (CPU), a network processor (NP), etc., and also may be a digital signal processor (DSP), an application specific integrated circuit (ASIC), a field-programmable gate array (FPGA) or other programmable logic devices, discrete gates, transistor logic devices, or discrete hardware components.

It may be understood that the structure shown in FIG. 4 is merely illustrative, and the electronic device further may include more or fewer components than those shown in FIG. 4, or is configured in a way different from that shown in FIG. 4. Various components shown in FIG. 4 may be realized by hardware, software or a combination thereof.

Hereinafter, the load resistance value determination method provided in the present disclosure is exemplarily described.

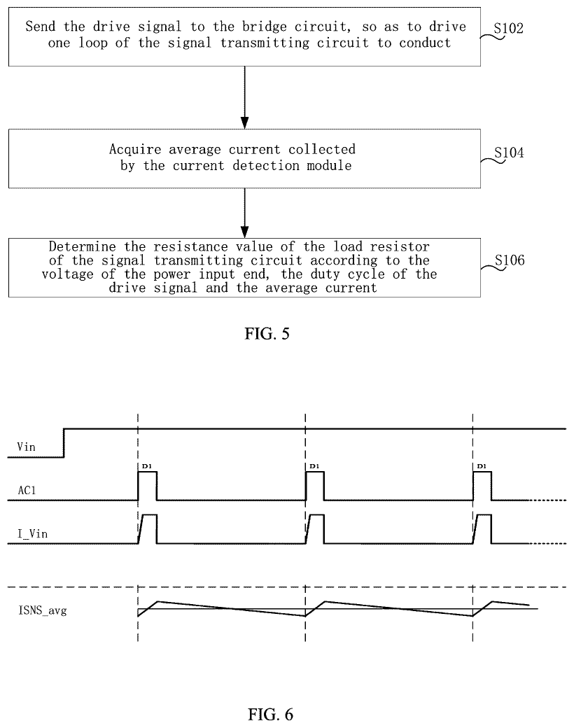

As an optional embodiment, referring to FIG. 5, the method includes:
S102, sending the drive signal to the bridge circuit, so as to drive one loop of the signal transmitting circuit to conduct;
S104, acquiring average current collected by the current detection module; and
S106, determining the resistance value of the load resistor of the signal transmitting circuit according to the voltage of the power input end, the duty cycle of the drive signal and the average current.

In the above, the drive signal provided in the present disclosure may be a low-duty-cycle signal. On one hand, using the low-duty-cycle drive signal may achieve a purpose of energy saving, and on the other hand, if a high-duty-cycle drive signal is used, current of a whole circuit may be large, further triggering an overcurrent protection mechanism of the signal transmitting circuit.

As an optional implementation mode, the drive signal may be a signal with a duty cycle greater than 0 and less than 10%. Certainly, the drive signal with other duty cycles also may be used, for example, a drive signal with a duty cycle of 20% is used, which is not limited herein. Moreover, the present disclosure does not limit amplitude of the drive signal, as long as the control unit, when at a high level, can control a switch to conduct.

In the above, it may be seen in conjunction with FIG. 3 that the load network includes the inductor Rx, the capacitor Cs and the switch Sw, and when in the signal transmission mode, the switch Sw is closed.

As an implementation mode, the bridge circuit includes a first switch, a second switch, a third switch and a fourth switch. Control terminals of the first switch, the second switch, the third switch and the fourth switch are all connected with the controller; a first terminal of the first switch and a first terminal of the fourth switch are connected with the current detection module; a second terminal of the first switch is connected with the load network and a first terminal of the second switch, respectively; a second terminal of the fourth switch is connected with the load network and a first terminal of the third switch, respectively; and a second terminal of the second switch and a second terminal of the third switch are grounded, wherein
The step of S102 includes: sending a first drive signal to the bridge circuit, so as to drive a loop where the first switch and the third switch are located to conduct according to a preset duty cycle, and the second switch and the fourth switch are turned off; or
sending a second drive signal to the bridge circuit, so as to drive a loop where the second switch and the fourth switch are located to conduct according to a preset duty cycle, and the first switch and the third switch are turned off.

It should be indicated that in the present disclosure, the first switch, the second switch, the third switch and the fourth switch are all transistors of the same model, and therefore, when determining the resistance value of the load resistor, any one of the two loops can be conducted.

For example, as shown in FIG. 3, in this case, the controller outputs the first drive signal, wherein specifically, the first drive signal actually includes four drive signals, pulse signals are output to the first switch and the third switch, and continuous low level signals are output to the second switch and the fourth switch, so that the first switch and the third switch are conducted, and in this case, a current direction is: the current detection module→the first switch→the inductor Rx→the third switch→ground.

Alternatively, when the controller outputs the second drive signal, wherein specifically, the first drive signal actually includes four drive signals, pulse signals are output to the second switch and the fourth switch, and continuous low level signals are output to the first switch and the third switch, so that the second switch and the fourth switch are conducted, and in this case, a current direction is: the current detection module→the fourth switch→the inductor Rx→the second switch→ground.

As an implementation mode, when determining the resistance value of the load resistor, the resistance value of the load resistor is proportional to the voltage of the power input end, proportional to square of the duty cycle of the drive signal, and inversely proportional to the average current. As shown in FIG. 6, it is a schematic diagram of working principle of the current detection module, wherein Vin represents the voltage of the power input end, AC1 represents a voltage of AC1 node, I_Vin represents input current, and ISNS_avg represents the average current detected by the current detection module. It may be understood that the current detection module actually determines an average value after smoothing the current, and uses it as the average current.

Therefore, the working principle of the load resistance value determination method in the present disclosure is as follows.

In conjunction with FIG. 3, when the switch Sw is closed, a low-duty-cycle pulse signal is sent out by the controller, to drive the switch corresponding to the full bridge to conduct, and a current pulse is generated on conducted loop and is detected by the current detection module included in the signal transmitting circuit. By the average current detected by the current detection module, the voltage of the power input end and the duty cycle, the resistance value of the load resistor may be obtained through further calculation.

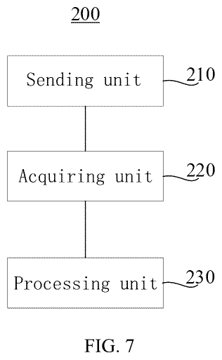

Based on the above implementation mode, referring to FIG. 7, the present disclosure further provides a load resistance value determination apparatus 200, applied to the controller of the signal transmitting circuit. The signal transmitting circuit further includes the bridge circuit, the load network and the current detection module. The bridge circuit is connected with the load network, the current detection module and the controller, respectively. The current detection module is further connected with the controller and the power input end, respectively. The apparatus includes:
a sending unit 210, configured to send the drive signal to the bridge circuit, so as to drive one loop of the signal transmitting circuit to conduct;
an acquiring unit 220, configured to acquire average current collected by the current detection module; and
a processing unit 230, configured to determine the resistance value of the load resistor of the signal transmitting circuit according to the voltage of the power input end, the duty cycle of the drive signal and the average current.

Optionally, the resistance value of the load resistor of the signal transmitting circuit is proportional to the voltage of the power input end, proportional to square of the duty cycle of the drive signal, and inversely proportional to the average current. Optionally, the sending unit is configured to send the drive signal with a duty cycle greater than 0 and less than 10% to the bridge circuit.

Moreover, as described above, the bridge circuit may include a first switch, a second switch, a third switch and a fourth switch. Control terminals of the first switch, the second switch, the third switch and the fourth switch are all connected with the controller; a first terminal of the first switch and a first terminal of the fourth switch are connected with the current detection module; a second terminal of the first switch is connected with the load network and a first terminal of the second switch, respectively; a second terminal of the fourth switch is connected with the load network and a first terminal of the third switch, respectively; and a second terminal of the second switch and a second terminal of the third switch are grounded, wherein
The sending unit is configured to send a first drive signal to the bridge circuit, so as to drive a loop where the first switch and the third switch are located to conduct according to a preset duty cycle, and the second switch and the fourth switch are turned off; or send a second drive signal to the bridge circuit, so as to drive a loop where the second switch and the fourth switch are located to conduct according to a preset duty cycle, and the first switch and the third switch are turned off.

It may be understood that corresponding steps of the load resistance value determination method may be implemented by the above units.

In conclusion, the embodiments of the present disclosure provide a load resistance value determination method, an apparatus, an electronic device and a storage medium. The load resistance value determination method is applied to a controller of a signal transmitting circuit. The signal transmitting circuit further includes a bridge circuit, a load network and a current detection module. The bridge circuit is connected with the load network, the current detection module and the controller, respectively. The current detection module is further connected with the controller and the power input end, respectively. Firstly, the drive signal is sent to the bridge circuit, so as to drive one loop of the signal transmitting circuit to conduct, then the average current collected by the current detection module is acquired, and the resistance value of the load resistor of the signal transmitting circuit is determined according to the voltage of the power input end, the duty cycle and the average current. In the present disclosure, since the resistance value of the load resistor can be determined according to the voltage of the power input end, the duty cycle and the average current, an effect of flexibly determining the resistance value of the load resistor is achieved, so that it is more flexible to control the bridge circuit.

In the embodiments provided in the present disclosure, it should be understood that the apparatus and method disclosed also may be implemented in other modes. The apparatus embodiments described above are merely illustrative, for example, the flow chart and blocks in the drawings show possible system architectures, functions and operations of the apparatus, method and computer program products according to embodiments of the present disclosure. In this regard, each block in the flow chart or block diagrams may represent a part of a module, a program segment or a code, which contains one or more executable instructions configured to realize a specified logical function.

It also should be noted that in some implementation modes as substitutions, the functions marked in the blocks also may take effect in an order different than that marked in the drawings. For example, two continuous blocks may be executed in parallel or in a reverse order, which depends on the function involved.

It also should be noted that each block or combination of the blocks in the block diagrams and or the flow chart may be implemented by a dedicated hardware-based system used to execute a specified function or action, or may be implemented by a combination of dedicated hardware and computer instructions.

Besides, various functional modules in various embodiments of the present disclosure may be integrated together to form one independent part, and it is also possible that the various modules exist independently, or that two or more modules are integrated to form one independent part.

If the function is implemented in a form of software functional module and is sold or used as an individual product, it may be stored in one computer readable storage medium. Based on such understanding, the technical solutions in essence or parts making contribution to the prior art or parts of the technical solutions of the present disclosure may be embodied in a form of a software product, and this computer software product is stored in a storage medium, including several instructions for making a computer device (which may be a personal computer, a server, a network device or the like) execute all or part of the steps of the methods of the embodiments of the present disclosure. The preceding storage medium includes various media in which program codes can be stored, such as USB flash disk, mobile hard disk, read-only memory, random access memory, diskette or compact disk.

Although the present disclosure is disclosed as above, the present disclosure is not limited thereto. Any one skilled in the art, without departing from the spirit and scope of the present disclosure, could make various modifications and amendments, and therefore, the scope of protection of the present disclosure should be determined by the scope defined by the claims.

1. A load resistance value determination method, applied to a controller of a signal transmitting circuit, wherein the signal transmitting circuit further comprises a bridge circuit, a load network and a current detection module, wherein the bridge circuit is connected with the load network, the current detection module and the controller, respectively, and the current detection module is further connected with the controller and a power input end, respectively, wherein the method comprises steps of:
sending a drive signal to the bridge circuit, so as to drive one loop of the signal transmitting circuit to conduct;
acquiring average current collected by the current detection module; and
determining a resistance value of a load resistor of the signal transmitting circuit according to a voltage of the power input end, a duty cycle of the drive signal and the average current.

2. The load resistance value determination method according to claim 1, wherein the resistance value of the load resistor of the signal transmitting circuit is proportional to the voltage of the power input end, proportional to square of the duty cycle of the drive signal, and inversely proportional to the average current.

3. The load resistance value determination method according to claim 1, wherein the step of sending a drive signal to the bridge circuit comprises:
sending the drive signal with a duty cycle greater than 0 and less than 10% to the bridge circuit.

4. The load resistance value determination method according to claim 1, wherein the bridge circuit comprises a first switch, a second switch, a third switch and a fourth switch, wherein control terminals of the first switch, the second switch, the third switch and the fourth switch are all connected with the controller; a first terminal of the first switch and a first terminal of the fourth switch are connected with the current detection module; a second terminal of the first switch is connected with the load network and a first terminal of the second switch, respectively; a second terminal of the fourth switch is connected with the load network and a first terminal of the third switch, respectively; and a second terminal of the second switch and a second terminal of the third switch are grounded; and
the step of sending a drive signal to the bridge circuit so as to drive one loop of the signal transmitting circuit to conduct comprises:
sending a first drive signal to the bridge circuit, so as to drive a loop where the first switch and the third switch are located to conduct according to a preset duty cycle, and the second switch and the fourth switch are turned off; or
sending a second drive signal to the bridge circuit, so as to drive a loop where the second switch and the fourth switch are located to conduct according to a preset duty cycle, and the first switch and the third switch are turned off.

5. A load resistance value determination apparatus, applied to a controller of a signal transmitting circuit, wherein the signal transmitting circuit further comprises a bridge circuit, a load network and a current detection module, wherein the bridge circuit is connected with the load network, the current detection module and the controller, respectively, and the current detection module is further connected with the controller and a power input end, respectively, wherein the apparatus comprises:
a sending unit, configured to send a drive signal to the bridge circuit, so as to drive one loop of the signal transmitting circuit to conduct;
an acquiring unit, configured to acquire average current collected by the current detection module; and
a processing unit, configured to determine a resistance value of a load resistor of the signal transmitting circuit according to a voltage of the power input end, a duty cycle of the drive signal and the average current.

6. The load resistance value determination apparatus according to claim 5, wherein the resistance value of the load resistor of the signal transmitting circuit is proportional to the voltage of the power input end, proportional to square of the duty cycle of the drive signal, and inversely proportional to the average current.

7. The load resistance value determination apparatus according to claim 5, wherein the sending unit is configured to send the drive signal with a duty cycle greater than 0 and less than 10% to the bridge circuit.

8. The load resistance value determination apparatus according to claim 5, wherein the bridge circuit comprises a first switch, a second switch, a third switch and a fourth switch, wherein control terminals of the first switch, the second switch, the third switch and the fourth switch are all connected with the controller; a first terminal of the first switch and a first terminal of the fourth switch are connected with the current detection module; a second terminal of the first switch is connected with the load network and a first terminal of the second switch, respectively; a second terminal of the fourth switch is connected with the load network and a first terminal of the third switch, respectively; and a second terminal of the second switch and a second terminal of the third switch are grounded; and
the sending unit is configured to send a first drive signal to the bridge circuit, so as to drive a loop where the first switch and the third switch are located to conduct according to a preset duty cycle, and the second switch and the fourth switch are turned off; or
send a second drive signal to the bridge circuit, so as to drive a loop where the second switch and the fourth switch are located to conduct according to a preset duty cycle, and the first switch and the third switch are turned off.

9. An electronic device, comprising:
a memory, configured to store one or more programs; and
a processor, wherein
the one or more programs, when executed by the processor, implements the method according to of claim 1.

10. (canceled)

11. The electronic device according to claim 9, wherein the resistance value of the load resistor of the signal transmitting circuit is proportional to the voltage of the power input end, proportional to square of the duty cycle of the drive signal, and inversely proportional to the average current.

12. The electronic device according to claim 9, wherein the step of sending a drive signal to the bridge circuit comprises:
sending the drive signal with a duty cycle greater than 0 and less than 10% to the bridge circuit.

13. The electronic device according to claim 9, wherein the bridge circuit comprises a first switch, a second switch, a third switch and a fourth switch, wherein control terminals of the first switch, the second switch, the third switch and the fourth switch are all connected with the controller; a first terminal of the first switch and a first terminal of the fourth switch are connected with the current detection module; a second terminal of the first switch is connected with the load network and a first terminal of the second switch, respectively; a second terminal of the fourth switch is connected with the load network and a first terminal of the third switch, respectively; and a second terminal of the second switch and a second terminal of the third switch are grounded; and
the step of sending a drive signal to the bridge circuit so as to drive one loop of the signal transmitting circuit to conduct comprises:
sending a first drive signal to the bridge circuit, so as to drive a loop where the first switch and the third switch are located to conduct according to a preset duty cycle, and the second switch and the fourth switch are turned off; or
sending a second drive signal to the bridge circuit, so as to drive a loop where the second switch and the fourth switch are located to conduct according to a preset duty cycle, and the first switch and the third switch are turned off.
